(19) United States
(12) Patent Application Publication
(10) Pub. No.: US 2022/0342313 A1
(43) Pub. Date: Oct. 27, 2022

(54) PROCESS LIQUID COMPOSITION FOR PHOTOLITHOGRAPHY AND PATTERN FORMING METHOD USING SAME

(71) Applicant: YOUNG CHANG CHEMICAL CO., LTD, Gyeongsangbuk-do (KR)

(72) Inventors: Su Jin LEE, Daegu (KR); Gi Hong KIM, Daegu (KR); Seung Hun LEE, Daegu (KR); Seung Hyun LEE, Daegu (KR)

(21) Appl. No.: 17/641,229

(22) PCT Filed: Jun. 24, 2020
(86) PCT No.: PCT/KR2020/008142

§ 371 Date: Mar. 8, 2022

(30) Foreign Application Priority Data
Sep. 26, 2019 (KR) 10-2019-0118885

(51) Int. Cl. G03F 7/42; C11D 1/00; C11D 3/20

(52) U.S. Cl. CPC G03F 7/426; C11D 1/004; C11D 3/2065

(57) ABSTRACT

A process liquid composition for moving a lifting defect level of a photoresist pattern having hydrophobicity represented by a contact angle of 75° or larger of a photoresist surface with respect to water in a photoresist patterning process, and a preparation method thereof are proposed. The process liquid composition includes 0.00001% to 0.1% by weight of a fluorine-based surfactant, 0.00001% to 1.0% by weight of a triol derivative, a tetraol derivative, or a mixture thereof, and the remaining proportion of water. The process liquid composition has a surface tension of 45 mN/m or less and a contact angle of 65° or smaller.

### TECHNICAL FIELD

The present invention relates to a process liquid composition for alleviating a lifting defect level of a photoresist pattern, the photoresist pattern having hydrophobicity represented by a contact angle of 75° or greater of a surface thereof with respect to water in a photoresist patterning process, and to a method of forming a photoresist pattern using the process liquid composition.

### BACKGROUND ART

Generally, a semiconductor device is manufactured by a lithographic process in which exposure light is infrared light with a wavelength of 193 nm, 248 nm, 365 nm, or the like. There is intense competition among semiconductor device manufacturers for reduction in a critical dimension (hereinafter referred to as a CD).

Accordingly, a light source creating a shorter wavelength is required to form a finer pattern. At the present time, a lithographic technology using extreme ultraviolet rays (EUV in a wavelength of 13.5 nm) is actively employed. A narrower wavelength may be realized using this lithographic technology.

However, the resistance of EUV photoresist to etching is not yet improved, and thus a photoresist pattern having a high aspect ratio still needs to be used. Accordingly, a pattern lifting defect occurs easily during development. Consequently, a process margin is greatly reduced in a manufacturing process.

To solve this problem, there is a demand to develop the technology for alleviating a level of a lifting defect that occurs while forming a fine pattern. The best way to alleviate a pattern lifting defect level may be to improve photoresist performance. However, there is a need to consider a situation where, in practice, it is difficult to develop new photoresist having performance that is satisfactory in terms of all aspects.

There is still a need to develop new photoresists. However, attempts have been made to alleviate the pattern lifting defect level in ways other than the development of new photoresist.

### DISCLOSURE

### Technical Problem

The objective of the present invention is to develop a process liquid composition for alleviating a level of a pattern lifting defect occurring after developing photoresist having hydrophobicity represented by a contact angle of 75° or a surface thereof with respect to water, and to develop a method of forming a photoresist pattern using the process liquid composition.

### Technical Solution

Various surfactants are used to manufacture a water-based process liquid composition that is used during a developing process. However, according to the present invention, an effective process liquid composition was manufactured using a fluorine-based surfactant.

The use of a hydrocarbon-based surfactant with a property like hydrophobicity in manufacturing the water-based process liquid composition in which ultra-pure water is mostly contained may lead to forming a hydrophobic sidewall of a photoresist, thereby reducing pattern melting or collapse. However, in this case, the hydrocarbon-based surfactants have a strong tendency to agglomerate, resulting in preventing a property of the process liquid composition from being uniform. Theretofore, there is a likelihood that the agglomerating hydrocarbon-based surfactants will cause defects while the process liquid composition is in use. That is, the use of the hydrocarbon-based surfactant requires an increase in the usage amount thereof for reducing the pattern melting. Thus, there is a concern that photoresist will be damaged. In addition, the excessive use of an unsuitable surfactant for the purpose of reducing surface tension of the process liquid composition to reduce a capillary force may lead to the pattern melting and rather may further cause the pattern collapse.

According to the present invention, it was verified that the use of a fluorine-based surfactant and an additional substance selected from triol derivatives, tetraol derivatives, and mixtures thereof achieved the noticeable effect of alleviating a pattern lifting defect level. The surface tension and contact angle, which were much more decreased than in the hydrocarbon-based surfactant, increased penetrability and spreadability, leading to contribution to formation of a fine pattern.

As a representative developing liquid that is currently used in most of the photolithographic developing processes, tetramethylammonium hydroxide diluted with pure water in the ratio that 2.38% by weight of tetramethylammonium hydroxide is mixed with 97.62% by weight of water is used.

It was verified that a pattern lifting defect was caused in a case where, in a photolithographic process, a photoresist pattern having hydrophobicity represented by a contact angle of 75° or greater of a surface thereof with respect to water was successively cleaned only with pure water after being developed. Furthermore, it was verified that, in a photolithographic process, a pattern collapse was also caused in a case where a process liquid composition resulting from tetramethylammonium hydroxide being contained in pure water was successively applied after developing or in a case where pure water was successively applied after developing and then the diluted tetramethylammonium hydroxide was applied thereafter.

It could be inferred that the pattern collapse was caused because the process liquid composition containing tetramethylammonium hydroxide weakened the exposed fine pattern and because the capillary force was great or non-uniform.

Therefore, in order to prevent the exposed-pattern collapse and to reduce the line width roughness (LWR) and the number of defects, there is a need to conduct study on a substance that exerts a relatively weaker force on the exposed pattern than tetramethylammonium hydroxide.

According to the present invention, it was verified that, in a case where a fluorine-based surfactant is used and a substance selected from triol derivatives, tetraol derivatives, and mixtures thereof is additionally used, the pattern collapse was prevented and the LWR and/or the number of defects was also reduced.

According to a desirable first embodiment of the present invention, there is provided a process liquid composition for alleviating a level of a lifting defect of a photoresist pattern, the lifting defect occurring during photoresist developing, the composition containing: 0.00001% to 0.1% by weight of a fluorine-based surfactant; 0.00001% to 1.0% by weight of a substance selected from the group consisting of triol derivatives, tetraol derivatives, and mixtures thereof; and the remaining proportion of water, in which the composition has a surface tension of 45 millinewton/meter (mN/m=1/1000 newton/meter) or less and a contact angle of 65° or smaller.

According to a more desirable second embodiment of the present invention, there is provided a process liquid composition for alleviating a level of a lifting defect of a photoresist pattern, the lifting defect occurring during photoresist developing, the composition containing: 0.0001% to 0.1% by weight of a fluorine-based surfactant; 0.00001% to 1.0% by weight of a substance selected from the group consisting of triol derivatives, tetraol derivatives, and mixtures thereof; and the remaining proportion of water, in which the composition has a surface tension of 45 mN/m or less and a contact angle of 65° or smaller.

According to a further desirable third embodiment of the present invention, there is provided a process liquid composition for alleviating a level of a lifting defect of a photoresist pattern, the lifting defect occurring during photoresist developing, the composition containing: 0.001% to 0.1% by weight of a fluorine-based surfactant; 0.00001% to 1.0% by weight of a substance selected from the group consisting of triol derivatives, tetraol derivatives, and mixtures thereof; and the remaining proportion of water, in which the liquid has a surface tension of 45 mN/m or less and a contact angle of 65° or smaller.

According to a most desirable fourth embodiment of the present invention, there is provided a process liquid composition for alleviating a level of a lifting defect of a photoresist pattern, the lifting defect occurring during photoresist developing, the composition containing: 0.001% to 0.1% by weight of a fluorine-based surfactant; 0.0001% to 1.0% by weight of a substance selected from the group consisting of triol derivatives, tetraol derivatives, and mixtures thereof; and the remaining proportion of water, in which the composition has a surface tension of 45 mN/m or less and a contact angle of 65° or smaller.

According to a most desirable fifth embodiment of the present invention, there is provided a process liquid composition for alleviating a level of a lifting defect of a photoresist pattern, the lifting defect occurring during photoresist developing, the composition containing: 0.001% to 0.1% by weight of a fluorine-based surfactant; 0.001% to 1.0% by weight of a substance selected from the group consisting of triol derivatives, tetraol derivatives, and mixtures thereof; and the remaining proportion of water, in which the liquid has a surface tension of 45 mN/m or less and a contact angle of 65° or smaller.

In the embodiments, the fluorine-based surfactant may be selected from the group consisting of fluoroacryl carboxylate, fluoroalkyl ether, fluoroalkylene ether, fluoroalkyl sulfate, fluoroalkyl phosphate, fluoroacryl copolymer, fluoro co-polymer, perfluorinated acid, perfluorinated carboxylate, perfluorianted sulfonate, and mixtures thereof.

In the embodiments, the triol derivative may be a C3 to C10 triol and may be selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6,-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydro naphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof.

In the embodiments, the tetraol derivative may be a C4 to C14 tetraol and may be selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2, 5,6-hexanetetraol, 1,3,4,5-hexanetetraol, 1,3,4,6-hexanetetraol, 2,3,4,5-hexanetetraol, 1,2,6,7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof.

According to an aspect of the present invention, there is provided a method of forming a photoresist pattern, the method including the steps of: (a) applying photoresist on a semiconductor substrate to form a photoresist film; (b) exposing the photoresist film to light and developing the photoresist film to form a photoresist pattern; and (c) cleaning the photoresist pattern with the process liquid composition.

It was thought that the pattern collapse was caused by the capillary force occurring between patterns when the patterns were cleaned with pure water after developing. However, it was experimentally recognized that only the reduction of the capillary force could neither completely prevent the pattern collapse nor reduce the number of the lifting defects.

The excessive use of the unsuitable surfactant for the purpose of reducing the surface tension of the process liquid composition to reduce the capillary force may lead to the pattern melting, resulting in an increase in the level of the pattern lifting defect.

In order to alleviate the level of the pattern lifting defect, it is important to select a surfactant that reduces the surface tension of the process liquid composition and at the same time to prevent the melting of the photoresist pattern.

The process liquid composition according to the present invention exerts an enhancing effect on photoresist and particularly achieves the effect of alleviating the level of the pattern lifting defect occurring while developing the photoresist having hydrophobicity represented by a contact angle of 75° or greater of a surface thereof with respect to water.

### Advantageous Effects

The process liquid composition according to the present invention achieves the effect of alleviating the level of the pattern lifting defect, the effect being unable to be achieved when only photoresist is used along to form a photoresist pattern having hydrophobicity represented by a contact angle of 75° C. or greater of a surface thereof with respect to water. The photoresist forming method including the step of cleaning the photoresist pattern with the process liquid composition can achieve the effect of greatly reducing manufacturing cost.

### BEST MODE

Hereinafter, the present invention will be described in detail.

The present invention, which is the result of conducting much research over a long period of time, relates to a “process liquid composition for alleviating a lifting defect level of a photoresist pattern, the process liquid composition including: 0.00001% to 0.1% by weight of a fluorine-based surfactant; 0.00001% to 1.0% by weight of a C3 to C10 triol derivative alone, a C4 to C14 tetraol derivative alone, or a mixture of the C3 to C10 triol derivative and the C4 to C14 tetraol derivative; and the remaining proportion of water. Herein, the fluorine-based surfactant is selected from the group consisting of fluoroacryl carboxylate, fluoroalkyl ether, fluoroalkylene ether, fluoroalkyl sulfate, fluoroalkyl phosphate, fluoroacryl copolymer, fluoro co-polymer, perfluorinated acid, perfluorinated carboxylate, perfluorianted sulfonate, and mixtures thereof. In addition, the C3 to C10 triol derivative is selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6,-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydro naphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof. In addition, the tetraol derivative is selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6,7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof. Composition components of the process liquid composition according to the present invention and a composition ratio among the components thereof were specified as shown in Examples 1 to 80. Composition components and ratios that were in contrast with the above-mentioned composition components and ratios, respectively, are specified as shown in Comparative Examples 1 to 13.

Herein after, the preferred examples of the invention and comparative examples will be described. However, the preferred examples described below are presented only for illustrative purposes and are not intended to limit the present invention.

### MODE FOR CARRYING OUT THE INVENTION

### Example 1

A process liquid composition for alleviating a collapse level of a photoresist pattern which contains 0.001% by weight of fluoroacryl carboxylate and 0.01% by weight of 1,2,3-propanetriol was prepared using the following method.

0.001% By weight of fluoroacryl carboxylate and 0.01% by weight of 1,2,3-propanetriol were added into the remaining proportion of distilled water and stirred for 5 hours. Then, the resulting liquid was filtered through a 0.01 μm filter to remove fine solid impurities. In this manner, the process liquid composition for alleviating the collapse level of the photoresist pattern was prepared.

### Example 2 to Example 80

Process liquid compositions for alleviating a defect level of the same photoresist pattern as in Example 1 were prepared according to composition components and ratios that were specified as shown in Tables 1 to 15.

### Comparative Example 1

Distilled water that was used as a cleaning liquid in the last process among typical semiconductor manufacturing processes was prepared.

### Comparative Example 2 to Comparative Example 13

For comparison with Examples, process liquid compositions were prepared in the same manner as in Example 1, according to the composition components and ratios that were specified as shown in Tables 1 to 15.

### Experimental Examples 1 to 80 and Comparative Experimental Examples 1 to 13

Measurements of pattern lifting defect levels were performed on silicon wafers on which patterns were formed using the compositions prepared in Examples 1 to 80 and Comparative Examples 1 to 13. The measurements are described as Experimental Examples 1 to 80 and Comparative Experimental Examples 1 to 13. The results of the measurements are shown in Table 16.

(1) Verification of Pattern Lifting Prevention

After exposure energy and focus were split, among a total of 89 blocks, the number of blocks in which a pattern did not collapse was detected using a critical dimension-scanning electron microscope (CD-SEM, manufactured by Hitachi, Ltd).

(2) Transparency

Transparency of each of the prepared process liquid composition was checked with the naked eye and was marked as a transparent or opaque process liquid composition.

(3) Surface Tension and Contact Angle

The surface tension and contact angle of each of the process liquid compositions were measured using a surface tension measuring instrument [the K-100 Force Tensiometer manufactured by KRÜSS GmbH] and a contact angle measuring instrument [the DSA-100 Drop Shape Analyzer manufactured by KRÜSS GmbH].

TABLE 1

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 1 | Fluoroacrylic | 0.001 | 1,2,3- | 0.01 | Distilled | 99.9890 |
| | carboxylate | | propanetriol | | water | |
| Example 2 | Fluoroalkyl ether | 0.001 | 1,2,3- | 0.01 | Distilled | 99.9890 |
| | | | propanetriol | | water | |
| Example 3 | Fluoroalkylene ether | 0.001 | 1,2,3- | 0.01 | Distilled | 99.9890 |
| | | | propanetriol | | water | |
| Example 4 | Fluoroalkyl sulfate | 0.001 | 1,2,3- | 0.01 | Distilled | 99.9890 |
| | | | propanetriol | | water | |
| Example 5 | Fluoroalkyl | 0.001 | 1,2,3- | 0.01 | Distilled | 99.9890 |
| | phosphate | | propanetriol | | water | |
| Example 6 | Fluoroacrylic | 0.001 | 1,2,3- | 0.01 | Distilled | 99.9890 |
| | copolymer | | propanetriol | | water | |
| Example 7 | Fluorine copolymer | 0.001 | 1,2,3- | 0.01 | Distilled | 99.9890 |
| | | | propanetriol | | water | |
| Example 8 | Perfluoric acid | 0.001 | 1,2,3- | 0.01 | Distilled | 99.9890 |
| | | | propanetriol | | water | |
| Example 9 | Perfluorinated | 0.001 | 1,2,3- | 0.01 | Distilled | 99.9890 |
| | carboxyl salts | | propanetriol | | water | |
| Example 10 | Perfluorinated | 0.001 | 1,2,3- | 0.01 | Distilled | 99.9890 |
| | sulfonate | | propanetriol | | water | |
| Comparative | — | — | — | — | Distilled | 100 |
| Example 1 | | | | | water | |

TABLE 2

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 11 | Fluoroacrylic | 0.001 | 1,2,3,4- | 0.01 | Distilled | 99.9890 |
| | carboxylate | | Butanetetraol | | water | |
| Example 12 | Fluoroalkyl ether | 0.001 | 1,2,3,4- | 0.01 | Distilled | 99.9890 |
| | | | Butanetetraol | | water | |
| Example 13 | Fluoroalkylene ether | 0.001 | 1,2,3,4- | 0.01 | Distilled | 99.9890 |
| | | | Butanetetraol | | water | |
| Example 14 | Fluoroalkyl sulfate | 0.001 | 1,2,3,4- | 0.01 | Distilled | 99.9890 |
| | | | Butanetetraol | | water | |
| Example 15 | Fluoroalkyl | 0.001 | 1,2,3,4- | 0.01 | Distilled | 99.9890 |
| | phosphate | | Butanetetraol | | water | |
| Example 16 | Fluoroacrylic | 0.001 | 1,2,3,4- | 0.01 | Distilled | 99.9890 |
| | copolymer | | Butanetetraol | | water | |
| Example 17 | Fluorine copolymer | 0.001 | 1,2,3,4- | 0.01 | Distilled | 99.9890 |
| | | | Butanetetraol | | water | |
| Example 18 | Perfluoric acid | 0.001 | 1,2,3,4- | 0.01 | Distilled | 99.9890 |
| | | | Butanetetraol | | water | |
| Example 19 | Perfluorinated | 0.001 | 1,2,3,4- | 0.01 | Distilled | 99.9890 |
| | carboxyl salts | | Butanetetraol | | water | |
| Example 20 | Perfluorinated | 0.001 | 1,2,3,4- | 0.01 | Distilled | 99.9890 |
| | sulfonate | | Butanetetraol | | water | |

TABLE 3

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 21 | Fluoroacrylic | 0.00001 | 1,2,3- | 0.01 | Distilled | 99.98999 |
| | carboxylate | | propanetriol | | water | |
| Example 22 | Fluoroacrylic | 0.0001 | 1,2,3- | 0.01 | Distilled | 99.9899 |
| | carboxylate | | propanetriol | | water | |
| Example 1 | Fluoroacrylic | 0.001 | 1,2,3- | 0.01 | Distilled | 99.9890 |
| | carboxylate | | propanetriol | | water | |
| Example 23 | Fluoroacrylic | 0.01 | 1,2,3- | 0.01 | Distilled | 99.9800 |
| | carboxylate | | propanetriol | | water | |
| Example 24 | Fluoroacrylic | 0.1 | 1,2,3- | 0.01 | Distilled | 99.8900 |
| | carboxylate | | propanetriol | | water | |
| Comparative | Fluoroacrylic | 1 | 1,2,3- | 0.01 | Distilled | 98.9900 |
| Example 2 | carboxylate | | propanetriol | | water | |

TABLE 4

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 25 | Fluoroalkyl | 0.00001 | 1,2,3- | 0.01 | Distilled | 99.98999 |
| | ether | | propanetriol | | water | |
| Example 26 | Fluoroalkyl | 0.0001 | 1,2,3- | 0.01 | Distilled | 99.9899 |
| | ether | | propanetriol | | water | |
| Example 2 | Fluoroalkyl | 0.001 | 1,2,3- | 0.01 | Distilled | 99.9890 |
| | ether | | propanetriol | | water | |
| Example 27 | Fluoroalkyl | 0.01 | 1,2,3- | 0.01 | Distilled | 99.9800 |
| | ether | | propanetriol | | water | |
| Example 28 | Fluoroalkyl | 0.1 | 1,2,3- | 0.01 | Distilled | 99.8900 |
| | ether | | propanetriol | | water | |
| Comparative | Fluoroalkyl | 1 | 1,2,3- | 0.01 | Distilled | 98.9900 |
| Example 3 | ether | | propanetriol | | water | |

TABLE 5

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 29 | Fluoroalkylene | 0.00001 | 1,2,3- | 0.01 | Distilled | 99.98999 |
| | ether | | propanetriol | | water | |
| Example 30 | Fluoroalkylene | 0.0001 | 1,2,3- | 0.01 | Distilled | 99.9899 |
| | ether | | propanetriol | | water | |
| Example 3 | Fluoroalkylene | 0.001 | 1,2,3- | 0.01 | Distilled | 99.9890 |
| | ether | | propanetriol | | water | |
| Example 31 | Fluoroalkylene | 0.01 | 1,2,3- | 0.01 | Distilled | 99.9800 |
| | ether | | propanetriol | | water | |
| Example 32 | Fluoroalkylene | 0.1 | 1,2,3- | 0.01 | Distilled | 99.8900 |
| | ether | | propanetriol | | water | |
| Comparative | Fluoroalkylene | 1 | 1,2,3- | 0.01 | Distilled | 98.9900 |
| Example 4 | ether | | propanetriol | | water | |

TABLE 6

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 33 | Fluoroalkyl | 0.00001 | 1,2,3- | 0.01 | Distilled | 99.98999 |
| | sulfate | | propanetriol | | water | |
| Example 34 | Fluoroalkyl | 0.0001 | 1,2,3- | 0.01 | Distilled | 99.9899 |
| | sulfate | | propanetriol | | water | |
| Example 4 | Fluoroalkyl | 0.001 | 1,2,3- | 0.01 | Distilled | 99.9890 |
| | sulfate | | propanetriol | | water | |
| Example 35 | Fluoroalkyl | 0.01 | 1,2,3- | 0.01 | Distilled | 99.9800 |
| | sulfate | | propanetriol | | water | |
| Example 36 | Fluoroalkyl | 0.1 | 1,2,3- | 0.01 | Distilled | 99.8900 |
| | sulfate | | propanetriol | | water | |
| Comparative | Fluoroalkyl | 1 | 1,2,3- | 0.01 | Distilled | 98.9900 |
| Example 5 | sulfate | | propanetriol | | water | |

TABLE 7

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 37 | Fluoroalkyl | 0.00001 | 1,2,3- | 0.01 | Distilled | 99.98999 |
| | phosphate | | propanetriol | | water | |
| Example 38 | Fluoroalkyl | 0.0001 | 1,2,3- | 0.01 | Distilled | 99.9899 |
| | phosphate | | propanetriol | | water | |
| Example 5 | Fluoroalkyl | 0.001 | 1,2,3- | 0.01 | Distilled | 99.9890 |
| | phosphate | | propanetriol | | water | |
| Example 39 | Fluoroalkyl | 0.01 | 1,2,3- | 0.01 | Distilled | 99.9800 |
| | phosphate | | propanetriol | | water | |
| Example 40 | Fluoroalkyl | 0.1 | 1,2,3- | 0.01 | Distilled | 99.8900 |
| | phosphate | | propanetriol | | water | |
| Comparative | Fluoroalkyl | 1 | 1,2,3- | 0.01 | Distilled | 98.9900 |
| Example 6 | phosphate | | propanetriol | | water | |

TABLE 8

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 41 | Fluoroacrylic | 0.00001 | 1,2,3- | 0.01 | Distilled | 99.98999 |
| | copolymer | | propanetriol | | water | |
| Example 42 | Fluoroacrylic | 0.0001 | 1,2,3- | 0.01 | Distilled | 99.9899 |
| | copolymer | | propanetriol | | water | |
| Example 6 | Fluoroacrylic | 0.001 | 1,2,3- | 0.01 | Distilled | 99.9890 |
| | copolymer | | propanetriol | | water | |
| Example 43 | Fluoroacrylic | 0.01 | 1,2,3- | 0.01 | Distilled | 99.9800 |
| | copolymer | | propanetriol | | water | |
| Example 44 | Fluoroacrylic | 0.1 | 1,2,3- | 0.01 | Distilled | 99.8900 |
| | copolymer | | propanetriol | | water | |
| Comparative | Fluoroacrylic | 1 | 1,2,3- | 0.01 | Distilled | 98.9900 |
| Example 7 | copolymer | | propanetriol | | water | |

TABLE 9

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 45 | Fluorine | 0.00001 | 1,2,3- | 0.01 | Distilled | 99.98999 |
| | copolymer | | propanetriol | | water | |
| Example 46 | Fluorine | 0.0001 | 1,2,3- | 0.01 | Distilled | 99.9899 |
| | copolymer | | propanetriol | | water | |
| Example 7 | Fluorine | 0.001 | 1,2,3- | 0.01 | Distilled | 99.9890 |
| | copolymer | | propanetriol | | water | |
| Example 47 | Fluorine | 0.01 | 1,2,3- | 0.01 | Distilled | 99.9800 |
| | copolymer | | propanetriol | | water | |
| Example 48 | Fluorine | 0.1 | 1,2,3- | 0.01 | Distilled | 99.8900 |
| | copolymer | | propanetriol | | water | |
| Comparative | Fluorine | 1 | 1,2,3- | 0.01 | Distilled | 98.9900 |
| Example 8 | copolymer | | propanetriol | | water | |

TABLE 10

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 49 | Perfluoric | 0.00001 | 1,2,3- | 0.01 | Distilled | 99.98999 |
| | acid | | propanetriol | | water | |
| Example 50 | Perfluoric | 0.0001 | 1,2,3- | 0.01 | Distilled | 99.9899 |
| | acid | | propanetriol | | water | |
| Example 8 | Perfluoric | 0.001 | 1,2,3- | 0.01 | Distilled | 99.9890 |
| | acid | | propanetriol | | water | |
| Example 51 | Perfluoric | 0.01 | 1,2,3- | 0.01 | Distilled | 99.9800 |
| | acid | | propanetriol | | water | |
| Example 52 | Perfluoric | 0.1 | 1,2,3- | 0.01 | Distilled | 99.8900 |
| | acid | | propanetriol | | water | |
| Comparative | Perfluoric | 1 | 1,2,3- | 0.01 | Distilled | 98.9900 |
| Example 9 | acid | | propanetriol | | water | |

TABLE 11

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 53 | Perfluorinated | 0.00001 | 1,2,3- | 0.01 | Distilled | 99.98999 |
| | carboxyl salts | | propanetriol | | water | |
| Example 54 | Perfluorinated | 0.0001 | 1,2,3- | 0.01 | Distilled | 99.9899 |
| | carboxyl salts | | propanetriol | | water | |
| Example 9 | Perfluorinated | 0.001 | 1,2,3- | 0.01 | Distilled | 99.9890 |
| | carboxyl salts | | propanetriol | | water | |
| Example 55 | Perfluorinated | 0.01 | 1,2,3- | 0.01 | Distilled | 99.9800 |
| | carboxyl salts | | propanetriol | | water | |
| Example 56 | Perfluorinated | 0.1 | 1,2,3- | 0.01 | Distilled | 99.8900 |
| | carboxyl salts | | propanetriol | | water | |
| Comparative | Perfluorinated | 1 | 1,2,3- | 0.01 | Distilled | 98.9900 |
| Example 10 | carboxyl salts | | propanetriol | | water | |

TABLE 12

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 57 | Perfluorinated | 0.00001 | 1,2,3- | 0.01 | Distilled | 99.98999 |
| | sulfonate | | propanetriol | | water | |
| Example 58 | Perfluorinated | 0.0001 | 1,2,3- | 0.01 | Distilled | 99.9899 |
| | sulfonate | | propanetriol | | water | |
| Example 10 | Perfluorinated | 0.001 | 1,2,3- | 0.01 | Distilled | 99.9890 |
| | sulfonate | | propanetriol | | water | |
| Example 59 | Perfluorinated | 0.01 | 1,2,3- | 0.01 | Distilled | 99.9800 |
| | sulfonate | | propanetriol | | water | |
| Example 60 | Perfluorinated | 0.1 | 1,2,3- | 0.01 | Distilled | 99.8900 |
| | sulfonate | | propanetriol | | water | |
| Comparative | Perfluorinated | 1 | 1,2,3- | 0.01 | Distilled | 98.9900 |
| Example 11 | sulfonate | | propanetriol | | water | |

TABLE 13

| | Surfactant | | Additive | | Additive | | | |
|---|---|---|---|---|---|---|---|---|
| | | Content | | Content | | Content | Distilled | Content |
| | | (% by | | (% by | | (% by | water | (% by |
| | Name | weight) | Name | weight) | Name | weight) | Name | weight) |
| Example 61 | Fluoroacrylic | 0.001 | 1,2,3- | 0.005 | 1,2,3,4- | 0.005 | Distilled | 99.9890 |
| | carboxylate | | propanetriol | | Butanetetraol | | water | |
| Example 62 | Fluoroalkyl | 0.001 | 1,2,3- | 0.005 | 1,2,3,4- | 0.005 | Distilled | 99.9890 |
| | ether | | propanetriol | | Butanetetraol | | water | |
| Example 63 | Fluoroalkylene | 0.001 | 1,2,3- | 0.005 | 1,2,3,4- | 0.005 | Distilled | 99.9890 |
| | ether | | propanetriol | | Butanetetraol | | water | |
| Example 64 | Fluoroalkyl | 0.001 | 1,2,3- | 0.005 | 1,2,3,4- | 0.005 | Distilled | 99.9890 |
| | sulfate | | propanetriol | | Butanetetraol | | water | |
| Example 65 | Fluoroalkyl | 0.001 | 1,2,3- | 0.005 | 1,2,3,4- | 0.005 | Distilled | 99.9890 |
| | phosphate | | propanetriol | | Butanetetraol | | water | |
| Example 66 | Fluoroacrylic | 0.001 | 1,2,3- | 0.005 | 1,2,3,4- | 0.005 | Distilled | 99.9890 |
| | copolymer | | propanetriol | | Butanetetraol | | water | |
| Example 67 | Fluorine | 0.001 | 1,2,3- | 0.005 | 1,2,3,4- | 0.005 | Distilled | 99.9890 |
| | copolymer | | propanetriol | | Butanetetraol | | water | |
| Example 68 | Perfluoric acid | 0.001 | 1,2,3- | 0.005 | 1,2,3,4- | 0.005 | Distilled | 99.9890 |
| | | | propanetriol | | Butanetetraol | | water | |
| Example 69 | Perfluorinated | 0.001 | 1,2,3- | 0.005 | 1,2,3,4- | 0.005 | Distilled | 99.9890 |
| | carboxyl salts | | propanetriol | | Butanetetraol | | water | |
| Example 70 | Perfluorinated | 0.001 | 1,2,3- | 0.005 | 1,2,3,4- | 0.005 | Distilled | 99.9890 |
| | sulfonate | | propanetriol | | Butanetetraol | | water | |

TABLE 14

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 71 | Fluoroacrylic | 0.001 | 1,2,3- | 0.00001 | Distilled | 99.99899 |
| | carboxylate | | propanetriol | | water | |
| Example 72 | Fluoroacrylic | 0.001 | 1,2,3- | 0.0001 | Distilled | 99.9989 |
| | carboxylate | | propanetriol | | water | |
| Example 73 | Fluoroacrylic | 0.001 | 1,2,3- | 0.001 | Distilled | 99.9980 |
| | carboxylate | | propanetriol | | water | |
| Example 1 | Fluoroacrylic | 0.001 | 1,2,3- | 0.01 | Distilled | 99.9890 |
| | carboxylate | | propanetriol | | water | |
| Example 74 | Fluoroacrylic | 0.001 | 1,2,3- | 0.1 | Distilled | 99.8990 |
| | carboxylate | | propanetriol | | water | |
| Example 75 | Fluoroacrylic | 0.001 | 1,2,3- | 1.0 | Distilled | 98.9990 |
| | carboxylate | | propanetriol | | water | |
| Comparative | Fluoroacrylic | 0.001 | 1,2,3- | 2.0 | Distilled | 97.9990 |
| Example 12 | carboxylate | | propanetriol | | water | |

TABLE 15

| | Surfactant | | Additive | | Distilled water | |
|---|---|---|---|---|---|---|
| | | Content (% | | Content (% | | Content (% |
| | Name | by weight) | Name | by weight) | Name | by weight) |
| Example 76 | Fluoroacrylic | 0.001 | 1,2,3,4- | 0.00001 | Distilled | 99.99899 |
| | carboxylate | | Butanetetraol | | water | |
| Example 77 | Fluoroacrylic | 0.001 | 1,2,3,4- | 0.0001 | Distilled | 99.9989 |
| | carboxylate | | Butanetetraol | | water | |
| Example 78 | Fluoroacrylic | 0.001 | 1,2,3,4- | 0.001 | Distilled | 99.9980 |
| | carboxylate | | Butanetetraol | | water | |
| Example 11 | Fluoroacrylic | 0.001 | 1,2,3,4- | 0.01 | Distilled | 99.9890 |
| | carboxylate | | Butanetetraol | | water | |
| Example 79 | Fluoroacrylic | 0.001 | 1,2,3,4- | 0.1 | Distilled | 99.8990 |
| | carboxylate | | Butanetetraol | | water | |
| Example 80 | Fluoroacrylic | 0.001 | 1,2,3,4- | 1.0 | Distilled | 98.9990 |
| | carboxylate | | Butanetetraol | | water | |
| Comparative | Fluoroacrylic | 0.001 | 1,2,3,4- | 2.0 | Distilled | 97.9990 |
| Example 13 | carboxylate | | Butanetetraol | | water | |

[Experimental Examples 1 to 80 and Comparative Experimental Examples 1 to 13] Measurements of pattern lifting defect levels, transparency values, contact angles, and surface tension values were performed on silicon wafers on which patterns are formed using the compositions prepared in Examples 1 to 80 and Comparative Examples 1 to 13. The measurements are described as Experimental Examples 1 to 80 and Comparative Experimental Examples 1 to 13. The results of the measurements are shown in Table 16.

(1) Verification of Pattern Lifting Prevention

After exposure energy and focus were split, among a total of 89 blocks, the number of blocks in which a pattern did not collapse was detected using a critical dimension-scanning electron microscope (CD-SEM, manufactured by Hitachi, Ltd).

(2) Transparency

Transparency of each of the prepared process liquid composition was checked with the naked eye and was marked as a transparent or opaque process liquid composition.

(3) Contact Angle and Surface Tension

The surface tension and contact angle of each of the process liquid compositions were measured using a surface tension measuring instrument [K-100, manufactured by KRÜSS GmbH] and a contact angle measuring instrument [DSA-100, manufactured by KRÜSS GmbH].

TABLE 16

| | Number of blocks | | | |
|---|---|---|---|---|
| | without pattern | | Contact | Surface |
| | lifting defects | Transparency | angle | tension |
| Experimental | 82 | Transparent | 50 | 28 |
| Example 1 | | | | |
| Experimental | 80 | Transparent | 58 | 32 |
| Example 2 | | | | |
| Experimental | 79 | Transparent | 54 | 30 |
| Example 3 | | | | |
| Experimental | 78 | Transparent | 60 | 32 |
| Example 4 | | | | |
| Experimental | 74 | Transparent | 59 | 31 |
| Example 5 | | | | |
| Experimental | 75 | Transparent | 61 | 33 |
| Example 6 | | | | |
| Experimental | 71 | Transparent | 63 | 41 |
| Example 7 | | | | |
| Experimental | 71 | Transparent | 57 | 40 |
| Example 8 | | | | |
| Experimental | 72 | Transparent | 59 | 38 |
| Example 9 | | | | |
| Experimental | 73 | Transparent | 58 | 35 |
| Example 10 | | | | |
| Experimental | 81 | Transparent | 56 | 32 |
| Example 11 | | | | |
| Experimental | 79 | Transparent | 59 | 34 |
| Example 12 | | | | |
| Experimental | 79 | Transparent | 57 | 30 |
| Example 13 | | | | |
| Experimental | 77 | Transparent | 62 | 33 |
| Example 14 | | | | |
| Experimental | 74 | Transparent | 61 | 31 |
| Example 15 | | | | |
| Experimental | 74 | Transparent | 63 | 34 |
| Example 16 | | | | |
| Experimental | 71 | Transparent | 64 | 38 |
| Example 17 | | | | |
| Experimental | 70 | Transparent | 57 | 36 |
| Example 18 | | | | |
| Experimental | 71 | Transparent | 58 | 35 |
| Example 19 | | | | |
| Experimental | 72 | Transparent | 58 | 33 |
| Example 20 | | | | |
| Experimental | 67 | Transparent | 63 | 43 |
| Example 21 | | | | |
| Experimental | 69 | Transparent | 59 | 34 |
| Example 22 | | | | |
| Experimental | 75 | Transparent | 45 | 26 |
| Example 23 | | | | |
| Experimental | 74 | Transparent | 40 | 23 |
| Example 24 | | | | |
| Experimental | 55 | Transparent | 62 | 45 |
| Example 25 | | | | |
| Experimental | 67 | Transparent | 60 | 28 |
| Example 26 | | | | |
| Experimental | 74 | Transparent | 55 | 29 |
| Example 27 | | | | |
| Experimental | 72 | Transparent | 54 | 27 |
| Example 28 | | | | |
| Experimental | 62 | Transparent | 63 | 41 |
| Example 29 | | | | |
| Experimental | 66 | Transparent | 57 | 34 |
| Example 30 | | | | |
| Experimental | 74 | Transparent | 54 | 26 |
| Example 31 | | | | |
| Experimental | 71 | Transparent | 50 | 23 |
| Example 32 | | | | |
| Experimental | 64 | Transparent | 64 | 41 |
| Example 33 | | | | |
| Experimental | 67 | Transparent | 60 | 35 |
| Example 34 | | | | |
| Experimental | 76 | Transparent | 59 | 28 |
| Example 35 | | | | |
| Experimental | 74 | Transparent | 52 | 24 |
| Example 36 | | | | |
| Experimental | 62 | Transparent | 62 | 40 |
| Example 37 | | | | |
| Experimental | 66 | Transparent | 60 | 35 |
| Example 38 | | | | |
| Experimental | 71 | Transparent | 57 | 27 |
| Example 39 | | | | |
| Experimental | 70 | Transparent | 56 | 23 |
| Example 40 | | | | |
| Experimental | 61 | Transparent | 64 | 41 |
| Example 41 | | | | |
| Experimental | 69 | Transparent | 61 | 34 |
| Example 42 | | | | |
| Experimental | 72 | Transparent | 58 | 25 |
| Example 43 | | | | |
| Experimental | 71 | Transparent | 57 | 25 |
| Example 44 | | | | |
| Experimental | 54 | Transparent | 63 | 45 |
| Example 45 | | | | |
| Experimental | 62 | Transparent | 62 | 39 |
| Example 46 | | | | |
| Experimental | 70 | Transparent | 59 | 31 |
| Example 47 | | | | |
| Experimental | 67 | Transparent | 57 | 30 |
| Example 48 | | | | |
| Experimental | 60 | Transparent | 60 | 43 |
| Example 49 | | | | |
| Experimental | 68 | Transparent | 58 | 40 |
| Example 50 | | | | |
| Experimental | 70 | Transparent | 54 | 30 |
| Example 51 | | | | |
| Experimental | 72 | Transparent | 52 | 27 |
| Example 52 | | | | |
| Experimental | 66 | Transparent | 62 | 43 |
| Example 53 | | | | |
| Experimental | 71 | Transparent | 60 | 37 |
| Example 54 | | | | |
| Experimental | 76 | Transparent | 57 | 30 |
| Example 55 | | | | |
| Experimental | 74 | Transparent | 52 | 28 |
| Example 56 | | | | |
| Experimental | 64 | Transparent | 63 | 43 |
| Example 57 | | | | |
| Experimental | 70 | Transparent | 57 | 34 |
| Example 58 | | | | |
| Experimental | 73 | Transparent | 56 | 25 |
| Example 59 | | | | |
| Experimental | 72 | Transparent | 53 | 23 |
| Example 60 | | | | |
| Experimental | 81 | Transparent | 53 | 33 |
| Example 61 | | | | |
| Experimental | 79 | Transparent | 58 | 33 |
| Example 62 | | | | |
| Experimental | 79 | Transparent | 55 | 34 |
| Example 63 | | | | |
| Experimental | 77 | Transparent | 61 | 33 |
| Example 64 | | | | |
| Experimental | 74 | Transparent | 60 | 31 |
| Example 65 | | | | |
| Experimental | 74 | Transparent | 61 | 34 |
| Example 66 | | | | |
| Experimental | 72 | Transparent | 63 | 40 |
| Example 67 | | | | |
| Experimental | 70 | Transparent | 55 | 39 |
| Example 68 | | | | |
| Experimental | 70 | Transparent | 56 | 37 |
| Example 69 | | | | |
| Experimental | 73 | Transparent | 58 | 34 |
| Example 70 | | | | |
| Experimental | 64 | Transparent | 44 | 21 |
| Example 71 | | | | |
| Experimental | 71 | Transparent | 45 | 23 |
| Example 72 | | | | |
| Experimental | 78 | Transparent | 48 | 26 |
| Example 73 | | | | |
| Experimental | 77 | Transparent | 52 | 31 |
| Example 74 | | | | |
| Experimental | 71 | Transparent | 55 | 33 |
| Example 75 | | | | |
| Experimental | 61 | Transparent | 49 | 25 |
| Example 76 | | | | |
| Experimental | 70 | Transparent | 50 | 28 |
| Example 77 | | | | |
| Experimental | 78 | Transparent | 52 | 30 |
| Example 78 | | | | |
| Experimental | 77 | Transparent | 54 | 34 |
| Example 79 | | | | |
| Experimental | 70 | Transparent | 58 | 35 |
| Example 80 | | | | |
| Comparative Test | 45 | Transparent | 87 | 71 |
| Example 1 | | | | |
| Comparative Test | 55 | Opaque | 40 | 18 |
| Example 2 | | | | |
| Comparative Test | 52 | Opaque | 54 | 22 |
| Example 3 | | | | |
| Comparative Test | 50 | Opaque | 49 | 20 |
| Example 4 | | | | |
| Comparative Test | 49 | Opaque | 53 | 19 |
| Example 5 | | | | |
| Comparative Test | 51 | Opaque | 52 | 21 |
| Example 6 | | | | |
| Comparative Test | 52 | Opaque | 57 | 23 |
| Example 7 | | | | |
| Comparative Test | 49 | Opaque | 59 | 26 |
| Example 8 | | | | |
| Comparative Test | 48 | Opaque | 51 | 41 |
| Example 9 | | | | |
| Comparative Test | 50 | Opaque | 54 | 27 |
| Example 10 | | | | |
| Comparative Test | 53 | Opaque | 53 | 24 |
| Example 11 | | | | |
| Comparative Test | 60 | Opaque | 59 | 37 |
| Example 12 | | | | |
| Comparative Test | 59 | Opaque | 60 | 38 |
| Example 13 | | | | |

From the comparison of Experimental examples 1 to 80 with Comparative Experimental Examples 1 to 13 on the basis of the result of conducting much research over a long period of time, it could be seen that, when the number of blocks in which a pattern did not collapse was 50 or greater and the composition exhibited a transparent property, a more improved result was obtained. That is, it was verified that when the compositions as in Experimental Examples 1 to 80 described below were used, the effect of reducing the pattern lifting defects was improved compared to the cases where the compositions as in Comparative Experimental Examples 1 to 13 were used. Each of the compositions as in Experimental Examples 1 to 80 included: 0.00001% to 0.1% by weight of a fluorine-based surfactant selected from the following, 0.00001% to 1.0% by weight of a C3 to C10 triol derivative alone selected from the following, a C4 to C14 tetraol alone selected from the following, or a mixture thereof; and 98.9% to 99.99998% of water, in which the fluorine-based surfactant were selected from fluoroacryl carboxylate, fluoroalkyl ether, fluoroalkylene ether, fluoroalkyl sulfate, fluoroalkyl phosphate, fluoroacryl copolymer, fluoro co-polymer, perfluorinated acid, perfluorinated carboxylate, and perfluorianted sulfonate; the C3 to C10 triol derivative was selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6,-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydro naphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof, and the C4 to C14 tetraol derivative is selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6,7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof.

In addition, among the compositions corresponding to Experimental Examples 1 to 80, the composition containing 0.0001% to 0.1% by weight of a fluorine-based surfactant selected from the following, 0.00001% to 1.0% by weight of a C3 to C10 triol derivative alone selected from the following, a C4 to C14 tetraol alone selected from the following, or a mixture thereof; and the remaining proportion of water improved the effect of reducing the pattern lifting defects compared to Comparative Experimental Examples 1 to 13, in which the fluorine-based surfactant was selected from fluoroacryl carboxylate, fluoroalkyl ether, fluoroalkylene ether, fluoroalkyl sulfate, fluoroalkyl phosphate, fluoroacryl copolymer, fluoro co-polymer, perfluorinated acid, perfluorinated carboxylate, and perfluorianted sulfonate; the C3 to C10 triol derivative was selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6,-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydro naphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof; and the C4 to C14 tetraol derivative was selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2, 5,6-hexanetetraol, 1,3,4,5-hexanetetraol, 1,3,4,6-hexanetetraol, 2,3,4,5-hexanetetraol, 1,2,6, 7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof.

Among the compositions as in Experimental Examples 1 to 80, the composition including 0.001% to 0.1% by weight of a fluorine-based surfactant selected from the following, 0.00001% to 1.0% by weight of a C3 to C10 triol derivative alone selected from the following, a C4 to C14 tetraol alone selected from the following, or a mixture thereof, and the remaining proportion of water improved the effect of reducing the pattern lifting defects compared to Comparative Experimental Examples 1 to 13, in which the fluorine-based surfactant were selected from fluoroacryl carboxylate, fluoroalkyl ether, fluoroalkylene ether, fluoroalkyl sulfate, fluoroalkyl phosphate, fluoroacryl copolymer, fluoro co-polymer, perfluorinated acid, perfluorinated carboxylate, and perfluorianted sulfonate; the C3 to C10 triol derivative was selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6,-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydro naphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof, and the C4 to C14 tetraol derivative is selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6, 7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof.

In addition, among the compositions corresponding to Experimental Examples 1 to 80, the composition containing 0.001% to 0.1% by weight of a fluorine-based surfactant selected from the following, 0.0001% to 1.0% by weight of a C3 to C10 triol derivative alone selected from the following, a C4 to C14 tetraol alone selected from the following, or a mixture thereof; and the remaining proportion of water improved the effect of reducing the pattern lifting defects compared to Comparative Experimental Examples 1 to 13, in which the fluorine-based surfactant was selected from fluoroacryl carboxylate, fluoroalkyl ether, fluoroalkylene ether, fluoroalkyl sulfate, fluoroalkyl phosphate, fluoroacryl copolymer, fluoro co-polymer, perfluorinated acid, perfluorinated carboxylate, and perfluorianted sulfonate; the C3 to C10 triol derivative was selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6,-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydro naphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof; and the C4 to C14 tetraol derivative was selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6, 7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof.

In addition, among the compositions corresponding to Experimental Examples 1 to 80, the composition containing 0.001% to 0.1% by weight of a fluorine-based surfactant selected from the following, 0.001% to 1.0% by weight of a C3 to C10 triol derivative alone selected from the following, a C4 to C14 tetraol alone selected from the following, or a mixture thereof; and the remaining proportion of water improved the effect of reducing the pattern lifting defects compared to Comparative Experimental Examples 1 to 13, in which the fluorine-based surfactant was selected from fluoroacryl carboxylate, fluoroalkyl ether, fluoroalkylene ether, fluoroalkyl sulfate, fluoroalkyl phosphate, fluoroacryl copolymer, fluoro co-polymer, perfluorinated acid, perfluorinated carboxylate, and perfluorianted sulfonate; the C3 to C10 triol derivative was selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6,-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydro naphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof; and the C4 to C14 tetraol derivative was selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6,7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof.

the result of measuring the collapse level of the photoresist pattern formed in Example 1 for evaluation was that the number of blocks in which the pattern did not collapse was 82, thereby having exhibited the best effect.

the result of measuring the collapse level of the photoresist pattern as in *Comparative Experimental Example 1 for evaluation was that the number of blocks in which the pattern did not collapse was 45.

The specific aspects of the present invention are described in detail above. It would be apparent to a person of ordinary skill in the art to which the present invention pertains that this specific description is only for the desired embodiments and do not impose any limitation on the scope of the present invention. Therefore, a substantial scope and a scope equivalent thereto must be defined by the following claims.

1. A process liquid composition for alleviating a lifting defect level of a photoresist pattern, the photoresist pattern having hydrophobicity represented by a contact angle of 75° or greater of a surface thereof with respect to water in a photoresist patterning process, the composition comprising a surfactant and having a surface tension of 45 mN/m or less and a contact angle of 65° or smaller.

2. The composition according to claim 1, comprising: 0.00001% to 0.1% by weight of a fluorine-based surfactant; 0.00001% to 1.0% by weight of a triol derivative, a tetraol derivative, or a mixture thereof; and the remaining proportion of water.

3. The composition according to claim 2, comprising: 0.0001% to 0.1% by weight of a fluorine-based surfactant; 0.00001% to 1.0% by weight of a triol derivative, a tetraol derivative, or a mixture thereof; and the remaining proportion of water.

4. The composition according to claim 3, comprising: 0.001% to 0.1% by weight of a fluorine-based surfactant; 0.00001% to 1.0% by weight of a triol derivative, a tetraol derivative, or a mixture thereof; and the remaining proportion of water.

5. The composition according to claim 4, comprising: 0.001% to 0.1% by weight of the fluorine-based surfactant; 0.0001% to 1.0% by weight of a triol derivative, a tetraol derivative, or a mixture thereof; and the remaining proportion of water.

6. The composition according to claim 5, comprising: 0.001% to 0.1% by weight of the fluorine-based surfactant; 0.001% to 1.0% by weight of a triol derivative, a tetraol derivative, or a mixture thereof; and the remaining proportion of water.

7. The composition according to claim 2, wherein the fluorine-based surfactant is selected from the group consisting of fluoroacryl carboxylate, fluoroalkyl ether, fluoroalkylene ether, fluoroalkyl sulfate, fluoroalkyl phosphate, fluoroacryl copolymer, fluoro co-polymer, perfluorinated acid, perfluorinated carboxylate, perfluorianted sulfonate, and mixtures thereof.

8. The composition according to claim 2, wherein the triol derivative is a C3 to C10 triol derivative selected from the group consisting of 1,2,3-propanetriol, 1,2,4-butanetriol, 1,1,4-butanetriol, 1,3,5-pentanetriol, 1,2,5-pentanetriol, 2,3,4-pentanetriol, 1,2,3-hexanetriol, 1,2,6-hexanetriol, 1,3,4-hexanetriol, 1,4,5-hexanetriol, 2,3,4-hexanetriol, 1,2,3-heptanetriol, 1,2,4-heptanetriol, 1,2,6-heptanetriol, 1,3,5-heptanetriol, 1,4,7-heptanetriol, 2,3,4-heptanetriol, 2,4,6-heptanetriol, 1,2,8-octanetriol, 1,3,5-octanetriol, 1,4,7-octanetriol, butane-1,1,1-triol, 2-methyl-1,2,3-propanetriol, 5-methylhexane-1,2,3-triol, 2,6-dimethyl-3-heptene-2,4,6,-triol, benzene-1,3,5-triol, 2-methyl-benzene-1,2,3-triol, 5-methyl-benzene-1,2,3-triol, 2,4,6,-trimethylbenzene-1,3,5-triol, naphthalene-1,4,5-triol, 5,6,7,8-tetrahydro naphthalene-1,6,7-triol, 5-hydromethylbenzene-1,2,3-triol, 5-isopropyl-2-methyl-5-cyclohexene-1,2,4-triol, 4-isopropyl-4-cyclohexene-1,2,3-triol, and mixtures thereof, and
wherein the tetraol derivative is a C4 to C14 tetraol derivative selected from the group consisting of 1,2,3,4-butanetetraol, 1,2,3,4-pentanetetraol, 1,2,4,5-pentanetetraol, 1,2,3,4-hexanetetraol, 1,2,3,5-hexanetetraol, 1,2,3,6-hexanetetraol, 1,2,4,5-hexanetetraol, 1,2,4,6-hexanetetraol, 1,2,5,6-hexanetetraol, 1,3,4,5-hexanetetraol, 1,3,4,6-hexanetetraol, 2,3,4,5-hexanetetraol, 1,2,6,7-heptanetetraol, 2,3,4,5-heptanetetraol, 1,1,1,2-octanetetraol, 1,2,7,8-octanetetraol, 1,2,3,8-octanetetraol, 1,3,5,7-octanetetraol, 2,3,5,7-octanetetraol, 4,5,6,7-octanetetraol, 3,7-dimethyl-3-octene-1,2,6,7-tetraol, 3-hexyne-1,2,5,6-tetraol, 2,5-dimethyl-3-hexyne-1,2,5,6-tetraol, anthracene-1,4,9,10-tetraol, and mixtures thereof.

9. A method of forming a photoresist pattern, the method comprising the steps of:
(a) applying photoresist on a semiconductor substrate to form a photoresist film; (b) exposing the photoresist film to light and developing the photoresist film to form a photoresist pattern; and (c) cleaning the photoresist pattern with the composition of claim 1.
